(19) United States
(12) Patent Application Publication
(10) Pub. No.: US 2013/0146770 A1
(43) Pub. Date: Jun. 13, 2013

(54) TERAHERTZ CONTINUOUS WAVE SYSTEM AND METHOD OF OBTAINING THREE-DIMENSIONAL IMAGE THEREOF

(71) Applicant: Electronics and Telecommunications Research In, Daejeon (KR)

(72) Inventors: Dong Suk JUN, Daejeon (KR); Kwang-Yong Kang, Daejeon (KR); Han-Cheol Ryu, Daejeon (KR); Je Ha Kim, Daejeon (KR)

(73) Assignee: Electronics and Telecommunications Research Institute, Daejeon (KR)

(21) Appl. No.: 13/685,282

(22) Filed: Nov. 26, 2012

(30) Foreign Application Priority Data
Dec. 8, 2011 (KR) 10-2011-0131127
Sep. 6, 2012 (KR) 10-2012-0098935

(51) Int. Cl. H01L 27/146

(52) U.S. Cl. CPC H01L 27/14625
USPC 250/338.4; 250/353; 250/341.1; 250/349

(57) ABSTRACT

A terahertz continuous wave system in accordance with the inventive concept may include a terahertz wave generator generating a terahertz continuous wave; a non-destructive detector measuring a change of the terahertz continuous wave by emitting the generated terahertz continuous wave to a sample and controlling a focal point of the emitted terahertz continuous wave while two-dimensionally moving the sample at predetermined intervals; and a three-dimensional image processor obtaining a three-dimensional image using two-dimensional images corresponding to the measured terahertz continuous wave.

### CROSS-REFERENCE TO RELATED APPLICATIONS

This U.S. non-provisional patent application claims priority under 35 U.S.C. §119 of Korean Patent Application No. 10-2011-0131127, filed on Dec. 8, 2011 and Korean Patent Application No. 10-2012-0098935, filed on Sep. 6, 2012, the entire contents of which are hereby incorporated by reference.

### BACKGROUND

The present inventive concept herein relates to a terahertz continuous wave system for a three-dimensional non-destructive molecular image and a method of obtaining a three-dimensional image thereof.

A terahertz band (100 GHz˜10 THz) exists at a boundary between an optical wave and an electronic wave and is a frequency band belatedly developed on a technical level. To open up a terahertz band, the terahertz band has been developed into a new electromagnetic wave technology using the latest laser technology and the latest semiconductor technology. A terahertz electromagnetic wave oscillates in a pulse wave type using an ultra-high speed photoconductive antenna (switch) by a femtosecond optical pulse and in a continuous wave type using an optical heterodyne method based on an optical mixer. A terahertz band continuous wave system has been gaining attention as a terahertz spectroscopy or an image measuring system due to strong points such as frequency selectivity, cost, size and a measuring time as compared with a pulse wave terahertz system.

### SUMMARY

Embodiments of the inventive concept provide a terahertz continuous wave system. The terahertz continuous wave system may include a terahertz wave generator generating a terahertz continuous wave; a non-destructive detector measuring a change of the terahertz continuous wave by emitting the generated terahertz continuous wave to a sample and controlling a focal point of the emitted terahertz continuous wave while two-dimensionally moving the sample at predetermined intervals; and a three-dimensional image processor obtaining a three-dimensional image using two-dimensional images corresponding to the measured terahertz continuous wave.

Embodiments of the inventive concept also provide a method of obtaining a three-dimensional image of terahertz continuous wave system. The method may include generating a terahertz continuous wave; emitting the generated terahertz continuous wave to a sample; changing a focal point of the terahertz continuous wave while moving the sample at predetermined intervals; measuring changes of the terahertz continuous wave; obtaining two-dimensional images corresponding to the measured changes of the terahertz continuous wave; obtaining a two-dimensional depth image using the two-dimensional images; and obtaining a three-dimensional image using the two-dimensional depth image.

### BRIEF DESCRIPTION OF THE FIGURES

Preferred embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout.

FIG. 1 is a drawing illustrating a terahertz continuous wave system in accordance with a first embodiment of the inventive concept.

FIG. 2 is a flow chart illustrating a process of obtaining a three-dimensional image from a data processing unit illustrated in FIG. 1.

FIG. 3 is a drawing for explaining a principle of controlling a focal distance using an aperture or a confocal pinhole illustrated in FIG. 1.

FIG. 4 is a drawing illustrating a terahertz continuous wave system in accordance with a second embodiment of the inventive concept.

FIG. 5 is a drawing for explaining a lens box constitution and a principle of controlling a focal distance illustrated in FIG. 4.

FIG. 6 is a drawing illustrating a terahertz continuous wave system in accordance with a third embodiment of the inventive concept.

FIG. 7 is a drawing for explaining a meta material lens box constitution and a principle of controlling a focal distance of the meta material lens box illustrated in FIG. 6.

FIG. 8 is a drawing illustrating a terahertz continuous wave system in accordance with a fourth embodiment of the inventive concept.

FIG. 9 is a drawing illustrating a terahertz continuous wave system in accordance with a fifth embodiment of the inventive concept.

FIG. 10 is a drawing illustrating a terahertz arrangement detector illustrated in FIG. 8 or 9.

FIG. 11 is a block diagram of an output circuit in accordance with some embodiments of the inventive concept.

FIG. 12 is a diagram illustrating a log-periodic antenna in accordance with some embodiments of the inventive concept.

FIGS. 13A and 13B are drawings illustrating resolutions when using a meta material lens and an optical lens in accordance with some embodiments of the inventive concept.

FIG. 14 is a drawing illustrating a sample of metal gasket and a sample of plastic gasket on a Teflon substrate in accordance with some embodiments of the inventive concept.

FIG. 15 is a drawing illustrating a two-dimensional depth image of a metal gasket and a plastic gasket measured by a terahertz wave passing through a Teflon substrate in accordance with some embodiments of the inventive concept.

FIG. 16 is a drawing illustrating a three-dimensional Cartesian integration image of the metal gasket and the plastic gasket illustrated in FIG. 15.

FIG. 17 is a drawing illustrating an image that an image processing is performed on a three-dimensional visualization image of the metal gasket and the plastic gasket illustrated in FIG. 15.

### DETAILED DESCRIPTION OF THE EMBODIMENTS

Embodiments of inventive concepts will be described more fully hereinafter with reference to the accompanying drawings, in which embodiments of the invention are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

A terahertz continuous wave system in accordance with the inventive concept can obtain a non-destructive three-dimensional image using a terahertz continuous wave of optical heterodyne system. In terahertz continuous wave of optical heterodyne system, if two continuous wave laser beams having the same strength and slightly different frequencies make an array of their wave fronts to enter an optical mixer formed on a photoconductive thin film such as low temperature grown GaAs (LTG-GaAs) having a short life of picoseconds or less, a current modulation of terahertz band corresponding to a difference frequency and a generated current is emitted as a terahertz band electromagnetic wave through an antenna. If controlling a focal distance of three-dimensional image by an aperture, a lot of two-dimensional tomography image formed according to a focal point of penetrated terahertz continuous wave can be obtained as one three-dimensional image. Instead of the aperture, combination of a confocal pinhole and a meta material lens and a combination of optical lens are possible.

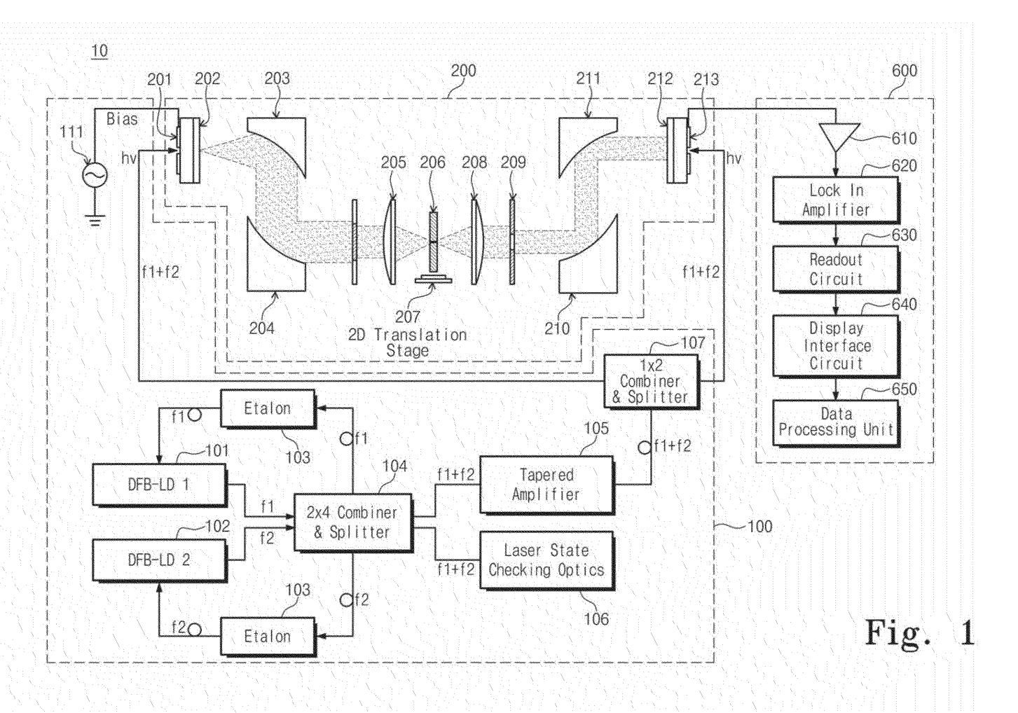

FIG. 1 is a drawing illustrating a terahertz continuous wave system in accordance with a first embodiment of the inventive concept. Referring to FIG. 1, the terahertz continuous wave system 10 includes a terahertz generator 100, a non-destructive detector 200 and a three-dimensional image processor 600.

The terahertz generator 100 generates a terahertz continuous wave in an optical heterodyne system. The terahertz generator 100 includes first and second dispersion feedback (DFB) lasers 101 and 102, a feedback control system 103, a 2×4 combiner and splitter 104, a semiconductor amplifier 105, a laser state checking optics 106, 1×2 combiner and splitter 107 and a power supply 111. To maximize flexibility and safety of the system, all the optical lines are constituted using an optical fiber. The two dispersion feedback (DFB) lasers 101 and 102 that operate at 853 nm and 855 nm respectively enter the 2×4 combiner and splitter 104 constituted by a biased maintaining optical fiber while operating in a single mode. Two output ports of the 2×4 combiner and splitter 104 are used to control and stabilize the lasers by feeding 1% of two 853 nm, 855 nm laser outputs back.

The feedback control system 103 can remove a frequency change due to heat of laser or an electromagnetic wave noise and thereby it can control an operation frequency of laser to a MHz level. The feedback control system 103 can stay an output of laser the same by controlling a current value of laser. One output port of the 2×4 combiner and splitter 104 is connected to an input of the semiconductor amplifier 105 that operates at 850 nm band to be used to amplify outputs of the two (DFB) lasers 101 and 102. The other output port of the 2×4 combiner and splitter 104 is connected to an input of the laser state checking optics 106 to be used to check and measure states of the two (DFB) lasers 101 and 102. An output of the 850 nm band semiconductor amplifier enters the 1×2 combiner and splitter 107 and the output is divided into 50:50 to be used to operate terahertz continuous wave transmission and reception devices 201 and 213.

The non-destructive detector 200 includes a photoconductive antenna for transmission 201, silicon and metal material lenses 202 and 212, parabolic minors 203, 204, 210 and 211, polyethylene lenses 205 and 208, a sample 206, a two-dimensional transmission stage 207, an aperture or confocal pinhole 209 and a detector array (also it is called a photoconductive antenna for reception) 213.

The non-destructive detector 200 emits the generated terahertz continuous wave to the sample 206 and receives the emitted terahertz continuous wave. When optical carriers generated by the two dispersion feedback (DFB) lasers 101 and 102 are accelerated by the applied voltage 111, an optical current of terahertz band is generated in an optical mixer of the photoconductive terahertz optical mixing device 201 for transmission. The optical current generated in the optical mixer is emitted to a free space through the silicon lens 202 attached to the back of a photoconductive substrate.

A terahertz continuous wave emitted from a transmitter progresses in a plane wave form through the parabolic minors 203 and 204 and focuses on the receiver 213 through the parabolic mirrors 210 and 211. The receiver operates in the same principal as the transmitter but the terahertz wave focused on the receiver functions as the applied voltage of the transmitter. Since in the receiver, an optical carrier is accelerated in proportion to an output of the received terahertz wave, an optical current being measured in the receiver is in proportion to the output of the received terahertz wave.

The two dispersion feedback (DFB) lasers 101 and 102 driving the terahertz optical mixing devices 210 and 213 are fitted with a 60 dB optical isolator and thereby they are safe against reflected lights caused by various optical devices. A phase sensitive detection using a mode lock-in amplifier 620 is performed to measure a fine current being generated.

In the non-destructive detector 200, a laser beam enters the photoconductive antenna (or an optical mixing device) 201 and 213 to emit an electromagnetic wave of picoseconds or less by a carrier generation caused by a photo excitement and a terahertz continuous wave is measured using the photoconductive antenna devices of the same structure. The non-destructive detector 200 measures a terahertz pulse at each location while moving a location of the sample 206 at regular intervals through the two-dimensional transmission stage 207.

The three-dimensional image processor 600 includes a low noise amplifier 610, a mode lock-in amplifier 620, an output circuit 630, a display interface circuit 640 and a data processing unit 650. The three-dimensional image processor 600 locates the sample 206 at a progressing route of terahertz continuous wave and obtains a three-dimensional image using a two-dimensional image corresponding to changes of the terahertz continuous wave by interaction between the terahertz continuous wave and the sample 206.

The terahertz continuous wave system 10 locates the aperture 209 at a progressing route of the terahertz continuous wave to measure a three-dimensional non-destructive molecule image and obtains a two-dimensional image having a different focal point location between the sample 206 and the terahertz continuous wave, and a three-dimensional image using a different image depth.

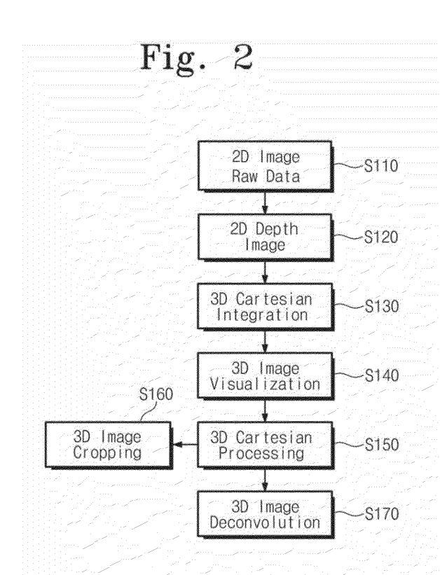

FIG. 2 is a flow chart illustrating a process of obtaining a three-dimensional image from a data processing unit illustrated in FIG. 1. Referring to FIG. 2, a process of obtaining a three-dimensional image is as follows. Two-dimensional raw image data obtained at each location is input (S110). A two-dimensional depth image is calculated from the two-dimensional raw image data which is input (S120). A three-dimensional Cartesian integration is performed using the calculated two-dimensional depth image (S130). A three-dimensional image is three-dimensionally visualized from the integrated image (S140). After that, the three-dimensional image is processed (S150). The processed three-dimensional image is cropped (S160) or deconvolution is performed on the processed three-dimensional image (S170).

A digital signal processing operation in accordance with some embodiments of the inventive concept sequentially performs the three-dimensional Cartesian integration (S130), the three-dimensional image visualization (S140) and the three-dimensional image processing (S150) to obtain a high resolution three-dimensional image. The three-dimensional Cartesian integration (S130) can use a volumetric pixel method well representing a regular hexahedron pixel having a specific volume. According to depth information of image being displayed, a digital signal processing operation of the inventive concept may perform a three-dimensional cropping (S160) or may perform a three-dimensional deconvolution to obtain a clearer image. The three-dimensional deconvolution may be performed to compensate a timing response, a noise and range tail of the detector 200.

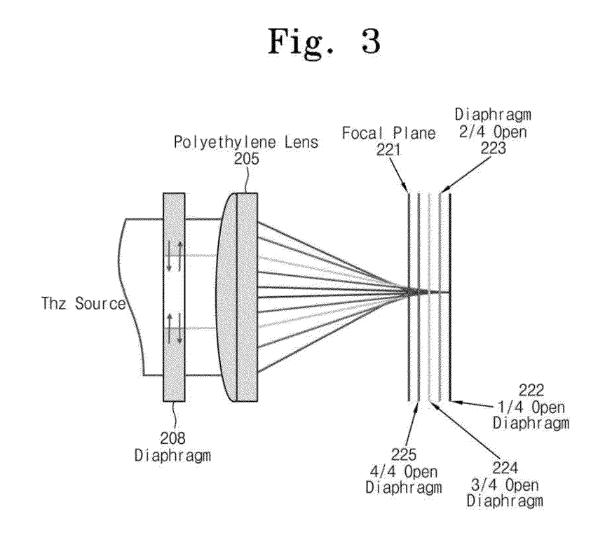

FIG. 3 is a drawing for explaining a principle of controlling a focal distance using an aperture or a confocal pinhole illustrated in FIG. 1. Referring to FIG. 3, to obtain a two-dimensional depth image, a focal plane 221 is obtained through the polyethylene lens 205 and to obtain a different two-dimensional depth image, an aperture is 4/4-open (225), 3/4-open (224), 2/4-open (223) and 1/4-open (222) using an aperture or the confocal pinhole 208.

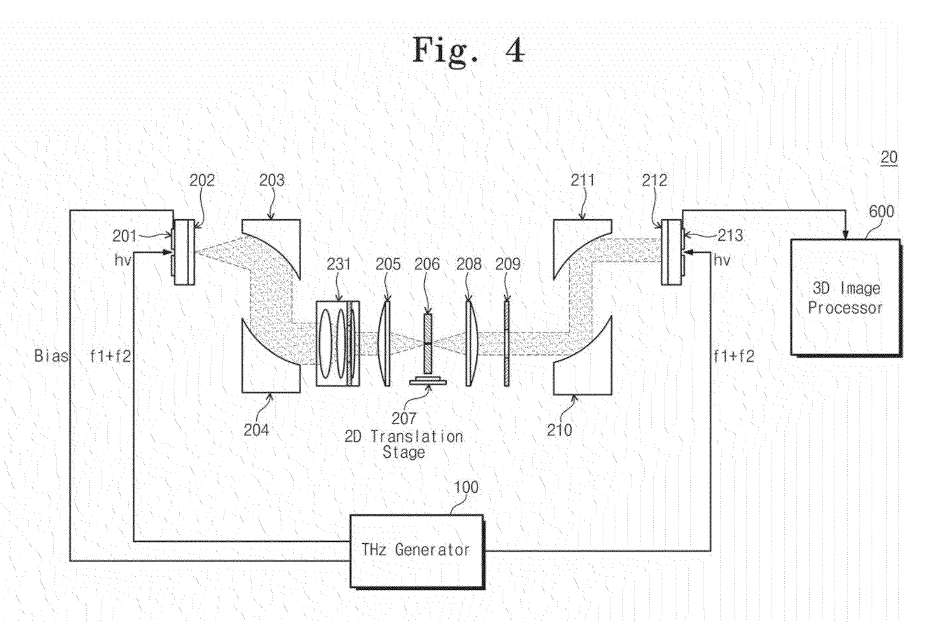

FIG. 4 is a drawing illustrating a terahertz continuous wave system in accordance with a second embodiment of the inventive concept. Referring to FIG. 4, a terahertz continuous wave system 20 further includes a lens box 231 as compared with the terahertz continuous wave system 10 of FIG. 1. The rest constituent elements are similar to those of the terahertz continuous wave system 10 of FIG. 1 and thus, description of the rest constituent elements will be omitted.

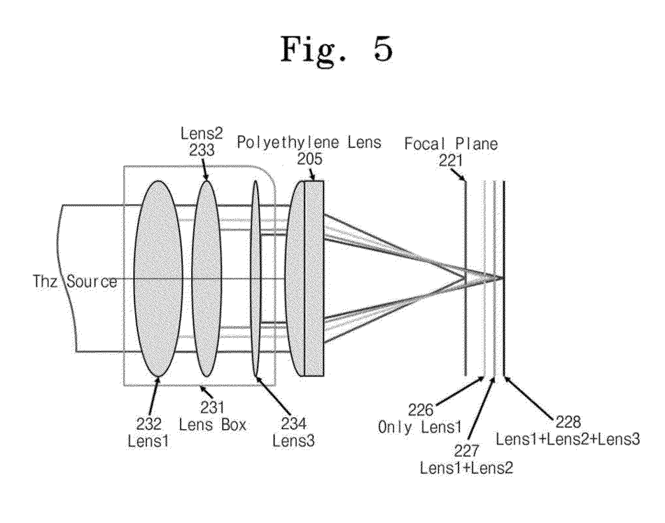

FIG. 5 is a drawing for explaining a lens box constitution and a principle of controlling a focal distance illustrated in FIG. 4. Referring to FIG. 5, to obtain a two-dimensional depth image, the focal plane 221 is obtained through the polyethylene lens 205 and to obtain a different two-dimensional depth image, different focal points 226, 227 and 228 may be obtained by a combination of lenses 232, 233 and 234 using the lens box 231. Focal points of the lenses 232, 233 and 234 can be controlled by thicknesses of the lenses 232, 233 and 234 and distances between the lenses 232, 233 and 234.

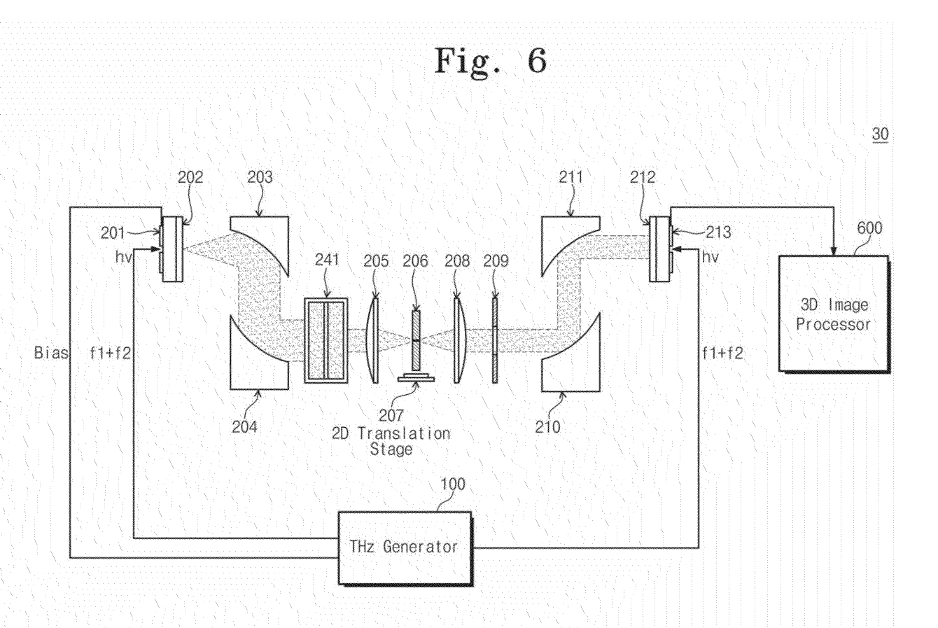

FIG. 6 is a drawing illustrating a terahertz continuous wave system in accordance with a third embodiment of the inventive concept. Referring to FIG. 6, a terahertz continuous wave system 30 further includes a meta material lens box 241 as compared with the terahertz continuous wave system 10 of FIG. 1. The rest constituent elements are similar to those of the terahertz continuous wave system 10 of FIG. 1 and thus, description of the rest constituent elements will be omitted.

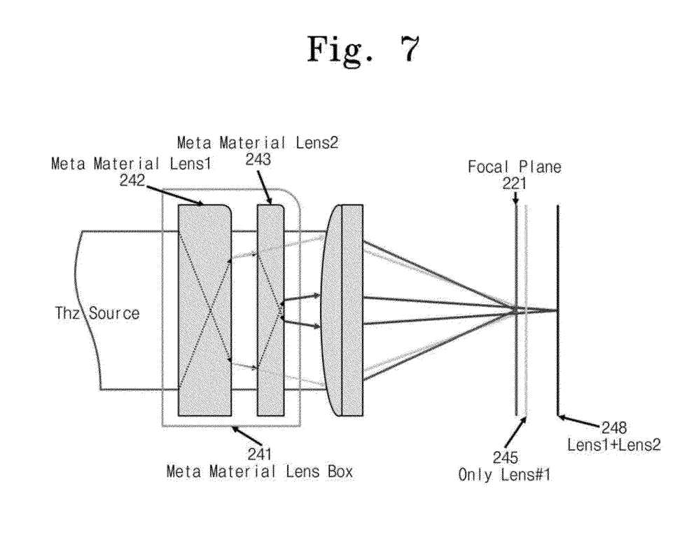

FIG. 7 is a drawing for explaining a meta material lens box constitution and a principle of controlling a focal distance of the meta material lens box illustrated in FIG. 6. Generally, focusing meta material lenses 242 and 243 that overcome a limitation of resolution which a photoconductive thin film pattern and an optical lens have are advantageous to maintain a high penetration ratio and a high refractive index. A material of an area (∈>0, μ>0, n=+\sqrt{∈μ}) having high penetration ratio and a high refractive index may be adopted in the photoconductive thin film pattern and the focusing meta material lens. The ∈ is dielectric permittivity and the μ is penetration ratio. The n is refractive index. Referring to FIG. 7, to obtain a two-dimensional depth image, the focal plane 221 is obtained through the polyethylene lens 208 and to obtain a different two-dimensional depth image, different focal points 245, and 248 may be obtained by a combination of lenses 242, and 243 using the meta material lens box 241. Focal points of the lenses 242 and 243 can be controlled by thicknesses of the lenses 242 and 243 and distances between the lenses 242 and 243.

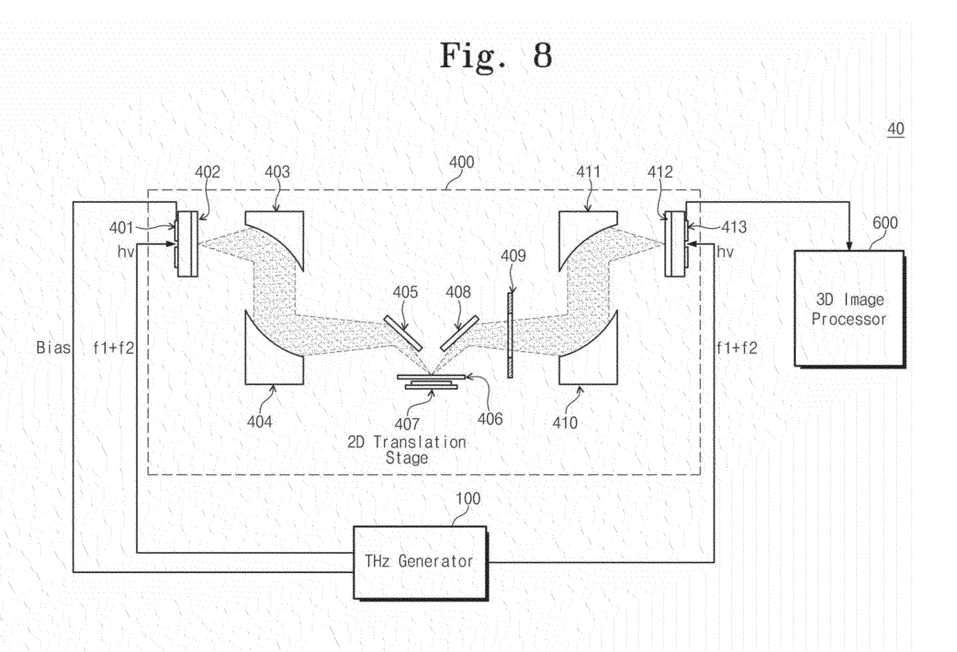

FIG. 8 is a drawing illustrating a terahertz continuous wave system in accordance with a fourth embodiment of the inventive concept. Referring to FIG. 8, a terahertz continuous wave system 40 includes a reflective type non-destructive detector 400 instead of the transmission-type non-destructive detector 200 of the terahertz continuous wave system 10 of FIG. 1. In the case that a pattern is formed on the front side of the sample and a metal is formed on the back side of the sample, since a terahertz wave cannot pass through the sample, the reflective type non-destructive detector is adopted. When in a packaged state, checking whether or not a bonding is formed or checking a semiconductor pattern, the reflective type non-destructive detector 400 is used very handy. Unlike the transmission-type non-destructive detector, mirrors 405 and 408 are used in the reflective type non-destructive detector.

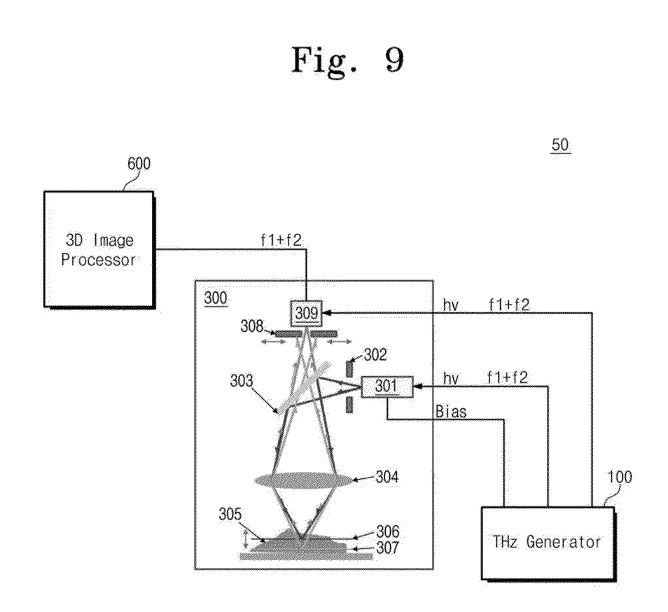

FIG. 9 is a drawing illustrating a terahertz continuous wave system in accordance with a fifth embodiment of the inventive concept. Referring to FIG. 9, a terahertz continuous wave system 50 includes a terahertz wave microscope 300 instead of the transmission-type non-destructive detector 200 of the terahertz continuous wave system 10 of FIG. 1. When an optical carrier generated by the two dispersion feedback (DFB) lasers 101 and 102 is accelerated by the applied voltage 111, an optical current of terahertz band is generated from an optical mixer of the terahertz optical mixing device 301. The optical current generated from the optical mixer is emitted to a free space through a silicon lens or a meta material lens attached onto the back of photoconductive substrate. A terahertz continuous wave emitted from a transmitter focuses a sample 305 on a focal plane 306 through an aperture or a confocal pinhole 302, a dichroic mirror 303 and a convex lens 304. As illustrated in FIGS. 5 and 7, a focal plane 307 may be controlled by a combination of lenses.

An image of the focal plane is detected from a terahertz detector 309 through the convex lens 304, the dichroic mirror 303 and a confocal pinhole 308.

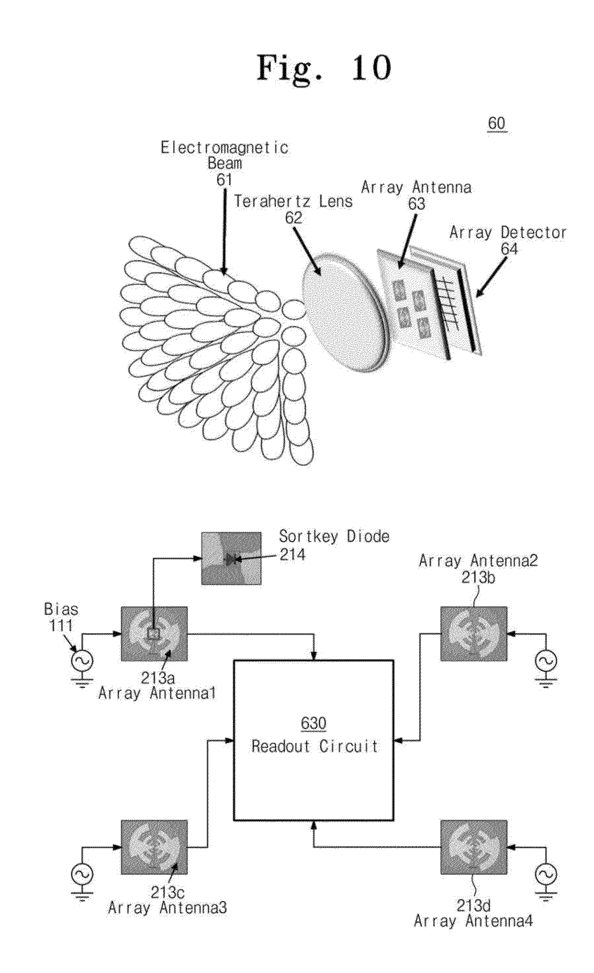

FIG. 10 is a drawing illustrating a terahertz arrangement detector illustrated in FIG. 8 or 9. Referring to FIG. 10, in a terahertz arrangement detector 60, an electromagnetic beam 61 passes through a terahertz wave lens 62 and an antenna array 63, and then is sensed by a detector array 64. The terahertz arrangement detector 60 can detect even an image of the object which cannot transmit a light. The antenna array 63 used in the terahertz arrangement detector 60 illustrated in FIG. 10 may be constituted by antennas 213a, 213b, 213c and 213d of terahertz area and a schottky diode 214 detecting a terahertz wave.

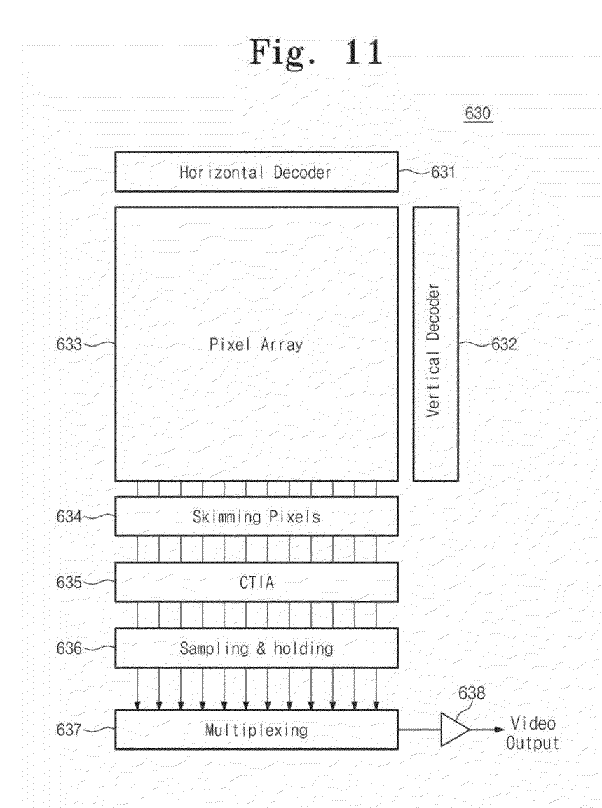

FIG. 11 is a block diagram of an output circuit 630 in accordance with some embodiments of the inventive concept. Referring to FIG. 11, an output signal of a pixel array 633 corresponding to a detected two-dimensional image is output through a horizontal decoder 631, a vertical decoder 632, skimming pixels 634, a capacitance trans impedance amplifier 635, a sampling & holding block 636, a multiplexing block 637 and an image amplifier 638.

The output circuit 630 supplies a power supply to a sequential row and detects a current through a resistor. A current flowing through a resistor by supplying a power supply to a pixel of each row is converted into a voltage by the capacitance trans impedance amplifier 635 which exists in each column. A pixel N row is integrated and voltages of N−1 row are input to the sampling and holding block 636. A multiplexing signal of the multiplexing block 637 is amplified in the image amplifier 638, and then is output. An electrical analog signal which is an output signal is converted into a digital signal. The converted digital signal is digitally processed. A digital signal processing obtains a two-dimensional depth image to obtain distance information of each pixel of the detector array 213 from two-dimensional image raw data (S110). By performing a digital signal processing, as described in FIG. 2, a three-dimensional image can be obtained using a two-dimensional depth image.

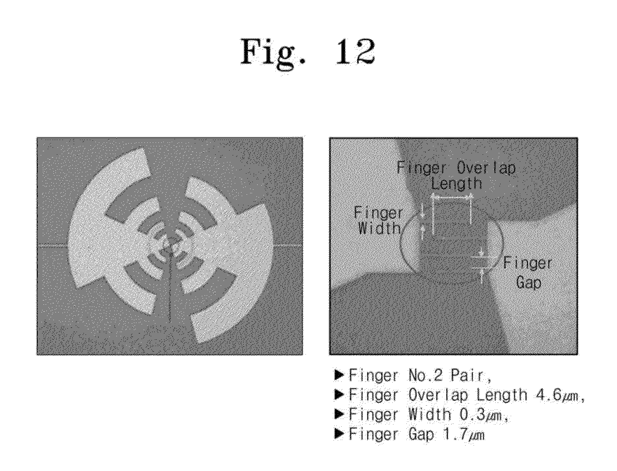

FIG. 12 is a diagram illustrating a log-periodic antenna in accordance with some embodiments of the inventive concept. Referring to FIG. 12, a terahertz continuous wave device uses a GaAs substrate of low temperature growth which has a great dark resistance, relatively good carrier mobility and a very short carrier life. As an optical mixer generating a current of terahertz band by an optical mixing, an interdigitated capacitor (IDC) type optical mixer is used to increase a photoelectric efficiency. A log-periodic antenna that can operate at a wide band is designed to emit the generated terahertz band current to a free space. The IDC optical mixer has a structure of two fingers, a finger overlap length of 4.6 m, a finger width of 0.3 m and a finger gap of 1.7 m. An electron beam lithography process has been used to manufacturing a fine pattern IDC optical mixer.

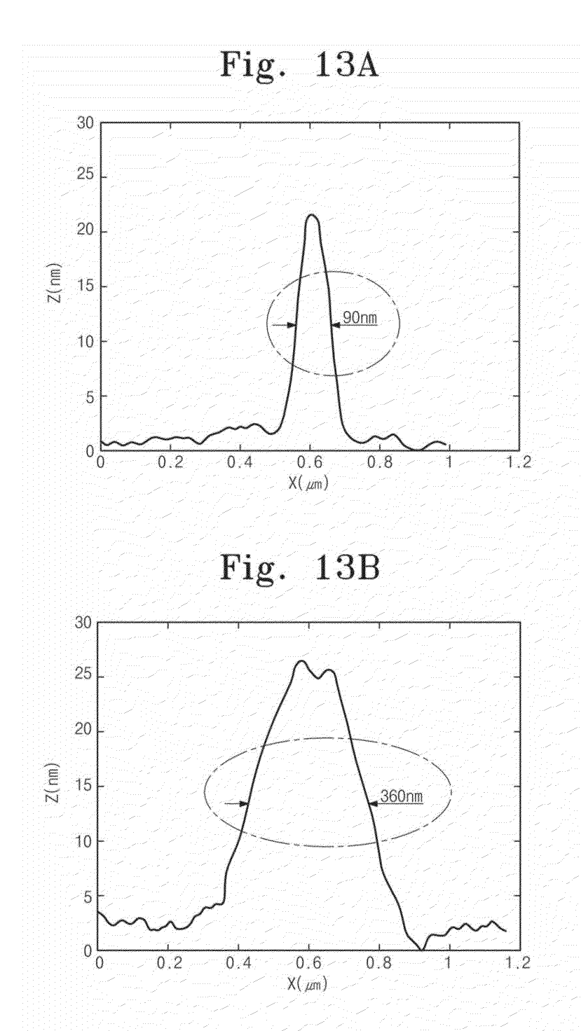

FIGS. 13A and 13B are drawings illustrating resolutions when using a meta material lens and an optical lens in accordance with some embodiments of the inventive concept. Referring to FIGS. 13A and 13B, a meta material lens has a resolution of 90 nm while a conventional optical lens has a resolution of 360 nm. The metal material lens in accordance with some embodiments of the inventive concept can obtain a high resolution as compared with a conventional optical lens.

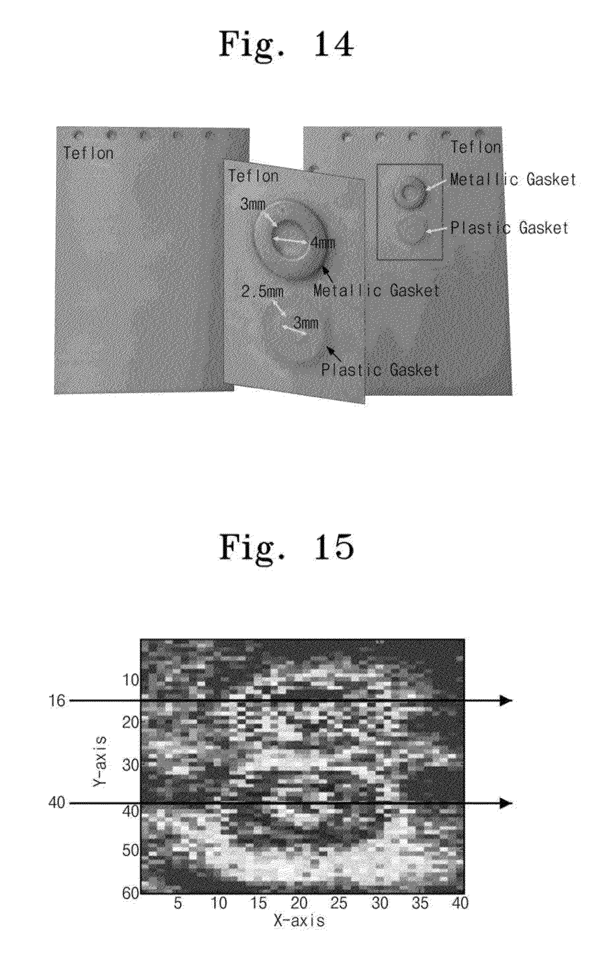

FIG. 14 is a drawing illustrating a sample of metal gasket and a sample of plastic gasket on a Teflon substrate in accordance with some embodiments of the inventive concept. Referring to FIG. 14, when a metal gasket and a plastic gasket are located on a front side of Teflon and a back side of Teflon, no object is sensed on the front side and an object appears to be hidden. A thickness of the used Teflon may be 1 nm, 2 nm, 3 nm or more. The metal gasket used in FIG. 14 is a ring-type gasket having a thickness of 1 nm, an inside diameter of 4 nm and an outside diameter of 10 nm. The plastic gasket used in FIG. 10 is a ring-type gasket having a thickness of 1.5 nm, an inside diameter of 3 nm and an outside diameter of 8 nm.

FIG. 15 is a drawing illustrating a two-dimensional depth image of a metal gasket and a plastic gasket measured by a terahertz wave passing through a Teflon substrate in accordance with some embodiments of the inventive concept. Referring to FIG. 15, a metal gasket at a coordinate 40 line on Y-axis is darkly seen. This is because a terahertz wave is totally reflected on a metal. A plastic gasket at a coordinate 16 line on Y-axis is seen similar to a Teflon plane. This is because a terahertz wave penetrates the plastic gasket.

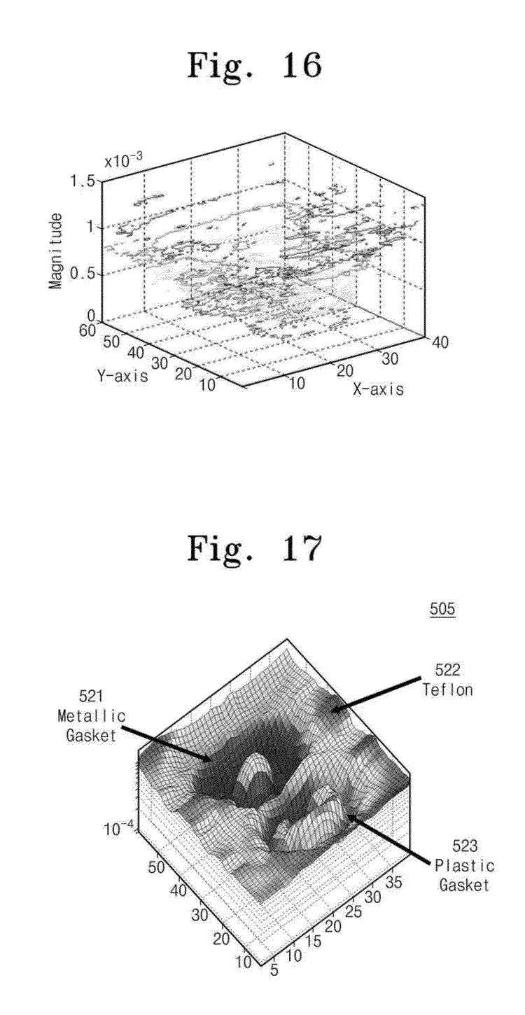

FIG. 16 is a drawing illustrating a three-dimensional Cartesian integration image of the metal gasket and the plastic gasket illustrated in FIG. 15.

FIG. 17 is a drawing illustrating an image that an image processing is performed on a three-dimensional visualization image of the metal gasket and the plastic gasket illustrated in FIG. 15.

By depositing a photoconductive thin film on a silicon substrate and embodying a meta material lens on a silicon substrate, the inventive concept can simplifies all manufacturing processes and remove a cause of error occurrence thereby reducing a time and costs.

The inventive concept simplifies a system constitution and a terahertz wave has penetrability of electronic wave and linearity of optical wave and thereby a three-dimensionally visualized image using a focal distance can be obtained.

The inventive concept can overcome a limitation of resolution of a conventional optical lens by using a meta material lens instead of a conventional optical lens. This can be foundation for mass production when a terahertz system is commercialized.

A non-destructive test of terahertz continuous wave system in accordance with the inventive concept can obtain spatial information of fault portions by controlling an aperture or confocal pinhole without making a radiation such as an X-ray, a gamma ray, etc. penetrate a test specimen. The non-destructive test can easily estimate a depth of defect and can easily detect a two-dimensional defect having a bad directivity.

Since a terahertz continuous wave system in accordance with the inventive concept does not emit radiations harmful to the human body, it is easily used in the field and has a rapid exploration speed and a low exploration cost.

A terahertz continuous wave system in accordance with the inventive concept has a high portability and a high sensitivity and can obtain location information of crack or spatial information of defect. A non-destructive test method of terahertz continuous wave system is safe and economical. A non-destructive test method of terahertz continuous wave system can increase work efficiency and can effectively find a surface defect.

A terahertz continuous wave system in accordance with the inventive concept can investigate a structure having a comparatively complicate shape and can detect even a fine defect. A terahertz continuous wave system increases a spatial resolution by a combination of a meta material lens and lens and a combination of meta material lenses. A terahertz continuous wave system does not need a high pressure current to form a magnetic field like a non-destructive magnetic particle (MT) and can easily detect a fine defect under the surface of object.

A terahertz continuous wave system in accordance with the inventive concept can further include a focusing arrangement meta material lens to obtain a three-dimensional image of object by controlling a focal point of a focusing meta material lens spaced apart from the focusing meta material lens.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

What is claimed is:

1. A terahertz continuous wave system comprising:
a terahertz wave generator generating a terahertz continuous wave;
a non-destructive detector measuring a change of the terahertz continuous wave by emitting the generated terahertz continuous wave to a sample and controlling a focal point of the emitted terahertz continuous wave while two-dimensionally moving the sample at predetermined intervals; and
a three-dimensional image processor obtaining a three-dimensional image using two-dimensional images corresponding to the measured terahertz continuous wave.

2. The terahertz continuous wave system of claim 1, wherein the non-destructive detector transmits the emitted terahertz continuous wave.

3. The terahertz continuous wave system of claim 2, wherein the non-destructive detector uses an aperture to control a focal point of the emitted terahertz continuous wave.

4. The terahertz continuous wave system of claim 2, wherein the non-destructive detector uses a confocal pinhole to control a focal point of the emitted terahertz continuous wave.

5. The terahertz continuous wave system of claim 4, wherein the non-destructive detector further comprises a lens box including a plurality of lenses to control a focal point of the emitted terahertz continuous wave.

6. The terahertz continuous wave system of claim 5, wherein the non-destructive detector further comprises a polyethylene lens to obtain a focal plane.

7. The terahertz continuous wave system of claim 4, wherein the non-destructive detector further comprises a meta material lens box including a polyethylene lens to obtain a focal plane and a plurality of meta material lenses to control a focal point of the emitted terahertz continuous wave.

8. The terahertz continuous wave system of claim 1, wherein the non-destructive detector is a terahertz wave microscope.

9. The terahertz continuous wave system of claim 1, wherein the non-destructive detector reflects the emitted terahertz continuous wave.

10. The terahertz continuous wave system of claim 9, wherein the non-destructive detector comprises a terahertz wave arrangement detector, and wherein in the terahertz wave arrangement detector, an electron beam passes through a terahertz lens and an antenna array, and then is sensed by a detector array.

11. The terahertz continuous wave system of claim 10, wherein the antenna array comprises at least one antenna of terahertz wave area and a schottky diode detecting the terahertz wave.

12. The terahertz continuous wave system of claim 1, wherein the terahertz wave generator dispersion feedback lasers generating optical signals having different frequencies to generate a terahertz continuous wave of optical heterodyne method.

13. The terahertz continuous wave system of claim 12, wherein the terahertz wave generator further comprises a feedback control system for stabilizing the dispersion feedback lasers.

14. The terahertz continuous wave system of claim 1, wherein the three-dimensional image processor further comprises a mode lock-in amplifier to measure a fine current corresponding to the terahertz continuous wave received from the non-destructive detector.

15. A method of obtaining a three-dimensional image of terahertz continuous wave system comprising:
generating a terahertz continuous wave;
emitting the generated terahertz continuous wave to a sample;
changing a focal point of the terahertz continuous wave while moving the sample at predetermined intervals;
measuring changes of the terahertz continuous wave;
obtaining two-dimensional images corresponding to the measured changes of the terahertz continuous wave;
obtaining a two-dimensional depth image using the two-dimensional images; and
obtaining a three-dimensional image using the two-dimensional depth image.

16. The method of obtaining a three-dimensional image of terahertz continuous wave system of claim 15, wherein further comprising cropping the obtained three-dimensional image according to a depth of the three-dimensional image.

17. The method of obtaining a three-dimensional image of terahertz continuous wave system of claim 15, further comprising performing deconvolution on the obtained three-dimensional image.

18. The method of obtaining a three-dimensional image of terahertz continuous wave system of claim 15, wherein obtaining the three-dimensional image comprises:
performing a three-dimensional Cartesian integration on the two-dimensional depth image;
performing a three-dimensional visualization on the Cartesian integrated image; and
processing the three-dimensionally visualized image.
